(19) United States
(12) Patent Application Publication
(10) Pub. No.: US 2023/0290823 A1
(43) Pub. Date: Sep. 14, 2023

(54) NANOSHEET WITH EARLY ISOLATION

(71) Applicant: INTERNATIONAL BUSINESS MACHINES CORPORATION, ARMONK, NY (US)

(72) Inventors: Ruilong Xie, Niskayuna, NY (US); Balasubramanian S. Pranatharthiharan, Santa Clara, CA (US); Julien Frougier, Albany, NY (US); Junli Wang, Slingerlands, NY (US)

(21) Appl. No.: 17/654,607

(22) Filed: Mar. 14, 2022

(51) Int. Cl. H01L 29/06; H01L 29/423; H01L 29/786; H01L 29/66; H01L 29/417; H01L 21/8234; H01L 21/768

(52) U.S. Cl. CPC H01L 29/0665; H01L 29/42392; H01L 29/78618; H01L 29/78696; H01L 29/66553; H01L 29/41733; H01L 21/823412; H01L 21/76843

(57) ABSTRACT

A semiconductor device including a nanodevice located on a substrate, where the nanodevice includes a plurality of nanosheets. Each of the plurality of nanosheets are spaced apart from each other by a first distance. A gate located on the substrate, where the gate surrounds each of the plurality of nanosheets. A first dielectric layer located on the substrate, where the first dielectric layer is located adjacent to a sidewall of the gate. The gate has a first thickness when measured from the sidewall of one of the plurality of nanosheets to a sidewall of the first dielectric layer, where the first thickness is larger than the first distance. An inner spacer located on the substrate, where the inner spacer is wraps around an end of each of the plurality of nanosheets. The inner spacer has a second thickness, where the second thickness is substantially equal to the first distance.

### BACKGROUND

The present invention generally relates to the field of nano devices, and more particularly to isolating nanosheets.

Nanosheet is the lead device architecture in continuing CMOS scaling. However, nanosheet technology has shown issues when scaling down such that as the devices become smaller and closer together, they are interfering with each other. Furthermore, the manufacturing steps for the one device could negatively affect the adjacent device.

### BRIEF SUMMARY

Additional aspects and/or advantages will be set forth in part in the description which follows and, in part, will be apparent from the description, or may be learned by practice of the invention.

A semiconductor device including a nanodevice located on a substrate, where the nanodevice includes a plurality of nanosheets. Each of the plurality of nanosheets are spaced apart from each other by a first distance. A gate located on the substrate, where the gate surrounds each of the plurality of nanosheets. A first dielectric layer located on the substrate, where the first dielectric layer is located adjacent to a sidewall of the gate. The gate has a first thickness when measured from the sidewall of one of the plurality of nanosheets to a sidewall of the first dielectric layer, where the first thickness is larger than the first distance. An inner spacer located on the substrate, where the inner spacer wraps around an end of each of the plurality of nanosheets. The inner spacer has a second thickness, where the second thickness is substantially equal to the first distance.

A semiconductor device including a first nanodevice located on a substrate, where the first nanodevice includes a plurality of first nanosheets. Each of the plurality of first nanosheets are spaced apart from each other by a first distance. A second nanodevice located on a substrate, where the second nanodevice includes a plurality of second nanosheets. Each of the plurality of second nanosheets are spaced apart from each other by a first distance. A first gate located on the substrate, where the first gate surrounds each of the plurality of first nanosheets. A second gate located on the substrate, where the second gate surrounds each of the plurality of second nanosheets. A first dielectric layer isolation pillar located on the substrate, where the first dielectric isolation pillar is located between the first gate and the second gate. A first dielectric layer located on the substrate, where the first dielectric layer is located around the first gate of the first nanodevice and the second gate of the second nanodevice. The first dielectric layer is located adjacent to a sidewall of the first gate and adjacent to the sidewall of the second gate, where the first gate has a first thickness when measured from the sidewall of one of the plurality of first nanosheets to a sidewall of the first dielectric layer. The first thickness is larger than the first distance. An inner spacer located on the substrate, where the inner spacer wraps around an end of each of the plurality of first nanosheets and wraps around an end of each of the plurality of second nanosheets. The inner spacer has a second thickness, where the second thickness is substantially equal to the first distance.

A method of forming a nanodevice including forming a plurality of nanosheets and plurality of sacrificially layers, where one sacrificial layer of the plurality of sacrificial layers is located above and below each of the plurality of nanosheets. Each of the plurality of nanosheets are spaced apart from each other by a first distance. Forming a shared sacrificial layer that combines each of the sacrificial layers of the plurality of sacrificial layers, where the shared sacrificial layer has a first thickness when measured from a sidewall of one of nanosheets to a sidewall of the shared sacrificial layer. The first thickness is equal to the first distance. Forming a dielectric liner along the sidewalls of the shared sacrificial layer and forming a first dielectric layer around the dielectric liner. Recessing the shared sacrificial layers at the end of the plurality of the nanosheets to create spacer for the formation of an inner spacer. Forming an inner spacer around the ends of each of the plurality of nanosheets, where the inner spacer has a second thickness when measured from a sidewall of one of nanosheets to a sidewall of the dielectric liner. The second thickness is equal to the first distance. Removing the shared sacrificial layer and the dielectric liner in a gate region of the nanodevice and forming a gate around each of the plurality of nanosheets. The gate has a third thickness when measured from a sidewall of one of nanosheets to a sidewall of the gate, where the third thickness is greater than the first distance.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top view of two nano devices, in accordance with the embodiment of the present invention.

FIG. 2 illustrates cross sections Y₁, Y₂, and Y₃ of the nano device showing the nano stack, in accordance with the embodiment of the present invention.

FIG. 3 illustrates cross section Y₁, Y₂, and Y₃ of the nano device after an initial patterning, in accordance with the embodiment of the present invention.

FIG. 4 illustrates cross sections Y₁, Y₂, and Y₃ of the nano device after the formation of the shallow trench isolation layer, in accordance with the embodiment of the present invention.

FIG. 5 illustrates cross section Y₁, Y₂, and Y₃ of the nano device after separating the nano stack into columns, in accordance with the embodiment of the present invention.

FIG. 6 illustrates cross sections Y₁, Y₂, and Y₃ of the nano device after the first layer and the ninth layer are replaced with a dielectric layer, in accordance with the embodiment of the present invention.

FIG. 7 illustrates cross section Y₁, Y₂, and Y₃ of the nano device after another shallow trench isolation fill and exposure of the nano stack columns, in accordance with the embodiment of the present invention.

FIG. 8 illustrates cross sections Y₁, Y₂, and Y₃ of the nano device after formation of a uniform sacrificial layer, in accordance with the embodiment of the present invention.

FIG. 9 illustrates cross section Y₁, Y₂, and Y₃ of the nano device after etching the uniform sacrificial layer, in accordance with the embodiment of the present invention.

FIG. 10 illustrates cross sections Y₁, Y₂, and Y₃ of the nano device after formation of a dielectric liner and a first dielectric layer, in accordance with the embodiment of the present invention.

FIG. 11 illustrates cross section Y₁, Y₂, and Y₃ of the nano device after formation of an oxide liner, a dummy gate and a second hardmask, in accordance with the embodiment of the present invention.

FIG. 12 illustrates cross section X of the nano device after patterning the dummy gate and the second hardmask, in accordance with the embodiment of the present invention.

FIG. 13 illustrates cross section Y₁ of the nano device after patterning the dummy gate and the second hardmask, in accordance with the embodiment of the present invention.

FIG. 14 illustrates cross section Y₂ of the nano device after patterning the dummy gate and the second hardmask, in accordance with the embodiment of the present invention.

FIG. 15 illustrates cross section Y₃ of the nano device after patterning the dummy gate and the second hardmask, in accordance with the embodiment of the present invention.

FIG. 16 illustrates cross section X of the nano device after formation of an upper spacer, in accordance with the embodiment of the present invention.

FIG. 17 illustrates cross section Y₁ of the nano device after formation of the upper spacer, in accordance with the embodiment of the present invention.

FIG. 18 illustrates cross section Y₂ of the nano device after formation of the upper spacer, in accordance with the embodiment of the present invention.

FIG. 19 illustrates cross section Y₃ of the nano device after pattering the formation of the upper spacer, in accordance with the embodiment of the present invention.

FIG. 20 illustrates cross section X of the nano device after etching the nano stack to form a plurality of gate regions and after the formation of the inner spacer, in accordance with the embodiment of the present invention.

FIG. 21 illustrates cross section Y₁ of the nano device after etching the nano stack to form a plurality of gate regions and after the formation of the inner spacer, in accordance with the embodiment of the present invention.

FIG. 22 illustrates cross section Y₂ of the nano device after etching the nano stack to form a plurality of gate regions and after the formation of the inner spacer, in accordance with the embodiment of the present invention.

FIG. 23 illustrates cross section Y₃ of the nano device after removal of the uniformed sacrificial layer and the nanosheets, in accordance with the embodiment of the present invention.

FIG. 24 illustrates cross section X of the nano device after formation of the source/drain, in accordance with the embodiment of the present invention.

FIG. 25 illustrates cross section Y₁ of the nano device after formation of the source/drain, in accordance with the embodiment of the present invention.

FIG. 26 illustrates cross section Y₂ of the nano device after formation of the source/drain, in accordance with the embodiment of the present invention.

FIG. 27 illustrates cross section Y₃ of the nano device after formation of the source/drain, in accordance with the embodiment of the present invention.

FIG. 28 illustrates cross section X of the nano device after formation of an interlayer dielectric, in accordance with the embodiment of the present invention.

FIG. 29 illustrates cross section Y₁ of the nano device after formation of gate cutes and a dielectric fill, in accordance with the embodiment of the present invention.

FIG. 30 illustrates cross section Y₂ of the nano device after formation of an interlayer dielectric, in accordance with the embodiment of the present invention.

FIG. 31 illustrates cross section Y₃ of the nano device after formation of an interlayer dielectric, in accordance with the embodiment of the present invention.

FIG. 32 illustrates cross section X of the nano device after removal of the dummy gate and the removal of the sacrificial layers, in accordance with the embodiment of the present invention.

FIG. 33 illustrates cross section Y₁ of the nano device after removal of the dummy gate and the removal of the sacrificial layers and the dielectric liner, in accordance with the embodiment of the present invention.

FIG. 34 illustrates cross section X of the nano device after the formation of the gate, in accordance with the embodiment of the present invention.

FIG. 35 illustrates cross section Y₁ of the nano device after the formation of the gate, in accordance with the embodiment of the present invention.

FIG. 36 illustrates cross section X of the nano device after formation of a second interlayer dielectric and a contact, in accordance with the embodiment of the present invention.

FIG. 37 illustrates cross section Y₁ of the nano device after formation of a second interlayer dielectric, a contact, and a metal plug, in accordance with the embodiment of the present invention.

FIG. 38 illustrates cross section Y₂ of the nano device after formation of a second interlayer dielectric, in accordance with the embodiment of the present invention.

FIG. 39 illustrates cross section Y₃ of the nano device after formation of a second interlayer dielectric and a contact, in accordance with the embodiment of the present invention.

FIG. 40 illustrates cross section X of the nano device after formation of a second interlayer dielectric and a contact, in accordance with the embodiment of the present invention.

FIG. 41 illustrates cross section Y₁ of the nano device after formation of a second interlayer dielectric, a contact, and a metal plug, in accordance with the embodiment of the present invention.

FIG. 42 illustrates cross section Y₂ of the nano device after formation of a second interlayer dielectric, in accordance with the embodiment of the present invention.

FIG. 43 illustrates cross section Y₃ of the nano device after formation of a second interlayer dielectric and a contact, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. The present invention is directed towards nanosheet devices where the width of the gate metal located on the sides of the nanosheet is larger than the spacing between the nanosheets. Furthermore, the width of the inner spacer located on the sides of the nanosheet is substantially equal to the spacing between the nanosheets.

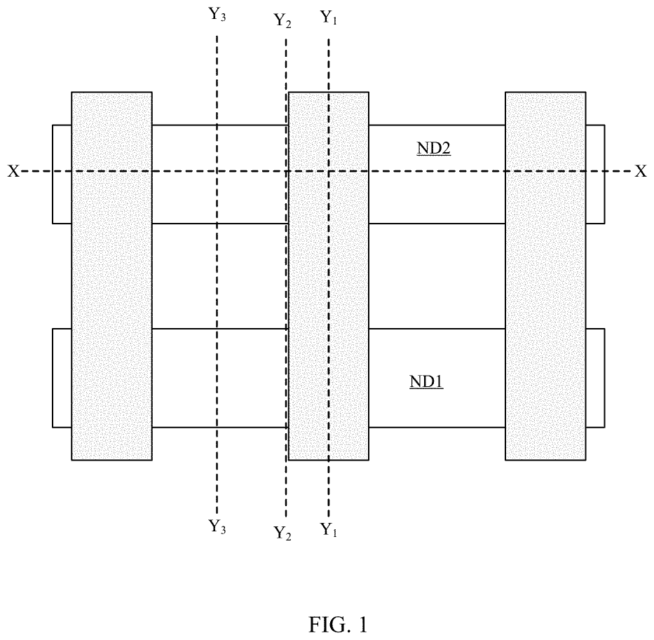

FIG. 1 illustrates a top view of two nano devices, in accordance with the embodiment of the present invention. The adjacent devices include a first nanodevice ND1 and a second nanodevice ND2. Cross-section X is a cross section perpendicular to the gates along the horizontal axis of the first nanodevice ND2 and cross-section Y₃ is a cross section parallel to the gates in the Source-Drain region across both nanodevices (ND1 and ND2). Cross-section Y₁ is a cross section through the gate region across both nanodevices (ND1 and ND2) and cross-section Y₂ is a cross section through the edge of the gate region at the location of the spacer and inner spacer.

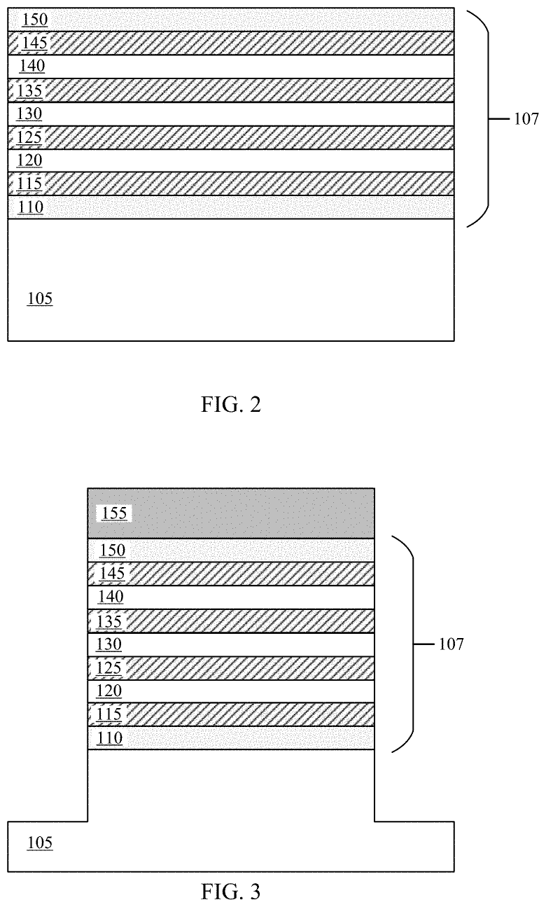

FIG. 2 illustrates cross sections Y₁, Y₂, and Y₃ of the nano device showing the nano stack 107, in accordance with the embodiment of the present invention. The nano stack 107 is located on top of a substrate 105. The substrate 105 can be, for example, a material including, but not necessarily limited to, silicon (Si), silicon germanium (SiGe), Si:C (carbon doped silicon), carbon doped silicon germanium (SiGe:C), III-V, II-V compound semiconductor or another like semiconductor. In addition, multiple layers of the semiconductor materials can be used as the semiconductor material of the substrate 105. In some embodiments, the substrate 105 includes both semiconductor materials and dielectric materials. The semiconductor substrate 105 may also comprise an organic semiconductor or a layered semiconductor such as, for example, Si/SiGe, a silicon-on-insulator or a SiGe-on-insulator. A portion or the entire semiconductor substrate 105 may also be comprised of an amorphous, polycrystalline, or monocrystalline. The semiconductor substrate 105 may be doped, undoped or contain doped regions and undoped regions therein.

The nano stack 107 includes a first layer 110, a second layer 115, a third layer 120, a fourth layer 125, a fifth layer 130, a sixth layer 135, a seventh layer 140, an eighth layer 145, and a ninth layer 150. The first layer 110 can be comprised of, for example, SiGe, where Ge is in the range of about 45% to 70%. A group of sacrificial layers includes the second layer 115, the fourth layer 125, the sixth layer 135, and the eighth layer 145. Each layer in the group of sacrificial layers can be comprised of, for example, SiGe, where Ge is in the range of about 15% to 35%. The third layer 120, the fifth layer 130, and the seventh layer 140 are nanosheets comprised of, for example, Si. The ninth layer 150 can be comprised of, for example, SiGe, where Ge is in the range of about 45% to 70%. The present invention illustrates that the nano stack 107 is comprised of three nanosheets (i.e., the third layer 120, the fifth layer 130, and the seventh layer 140) but this is not meant to be seen as limiting. The number of nanosheets in the nano device can be less than for more than three nanosheets.

FIG. 3 illustrates cross section Y₁, Y₂, and Y₃ of the nano device after an initial patterning, in accordance with the embodiment of the present invention. A hardmask 155 is formed on top of the ninth layer 150. The nano stack 107 is patterned to an initial design. Part of the substrate 105 is removed during the patterning process.

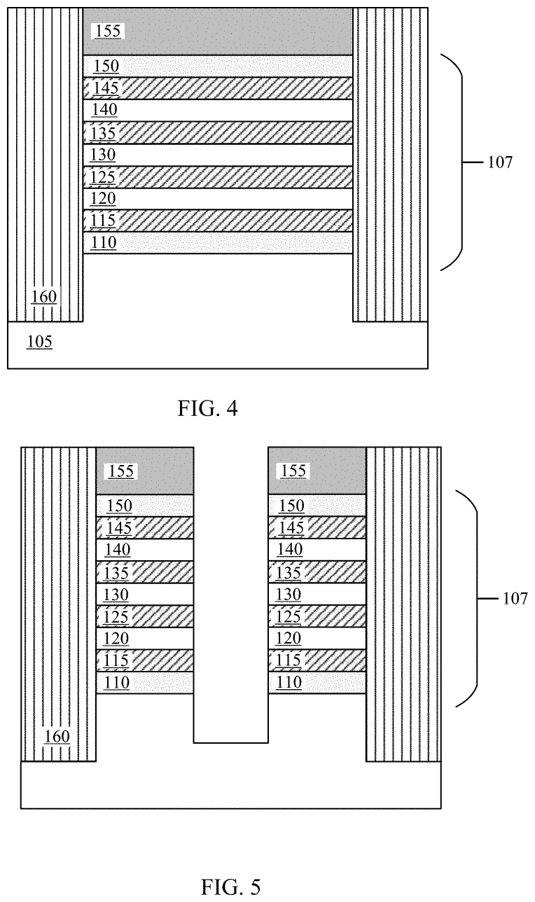

FIG. 4 illustrates cross sections Y₁, Y₂, and Y₃ of the nano device after the formation of the shallow trench isolation layer 160, in accordance with the embodiment of the present invention. A shallow trench isolation layer 160 is formed along the sides of the nano stack 107, where the shallow trench isolation layer 160 is located on top of the substrate 105. FIG. 5 illustrates cross section Y₁, Y₂, and Y₃ of the nano device after separating the nano stack 107 into columns, in accordance with the embodiment of the present invention. The nano stack 107 is patterned for a second time to form a plurality of columns.

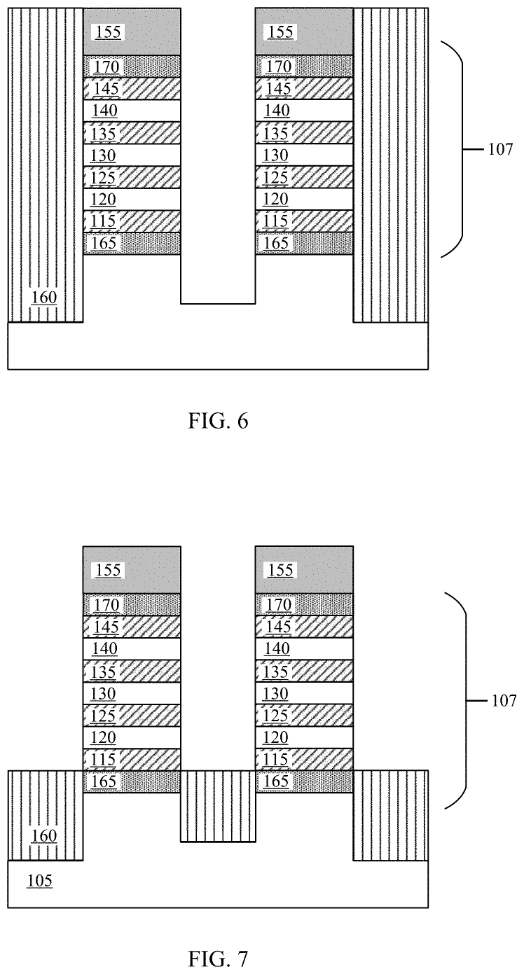

FIG. 6 illustrates cross sections Y₁, Y₂, and Y₃ of the nano device after the first layer 110 and the ninth layer 150 are replaced with a dielectric layer, in accordance with the embodiment of the present invention. The first layer 110 and the ninth layer 150 are selectively removed. Theses layers can be selectively targeted because of the higher concentration of Ge when compared to the group of sacrificial layers. A bottom dielectric layer 165 is formed between the substrate 105 and the second layer 115. An upper dielectric layer 170 is formed between the eighth layer 145 and the hardmask 155. The bottom dielectric layer 165 and the upper dielectric layer 170 can be comprised of the same or different dielectric materials.

FIG. 7 illustrates cross section Y₁, Y₂, and Y₃ of the nano device after another shallow trench isolation layer 160 fill and exposure of the nano stack columns, in accordance with the embodiment of the present invention. Additional shallow trench isolation layer 160 material is deposited in the areas exposed by the second pattern to form the nano stack columns. The shallow trench isolation layer 160 is etched back to expose the nano stack columns.

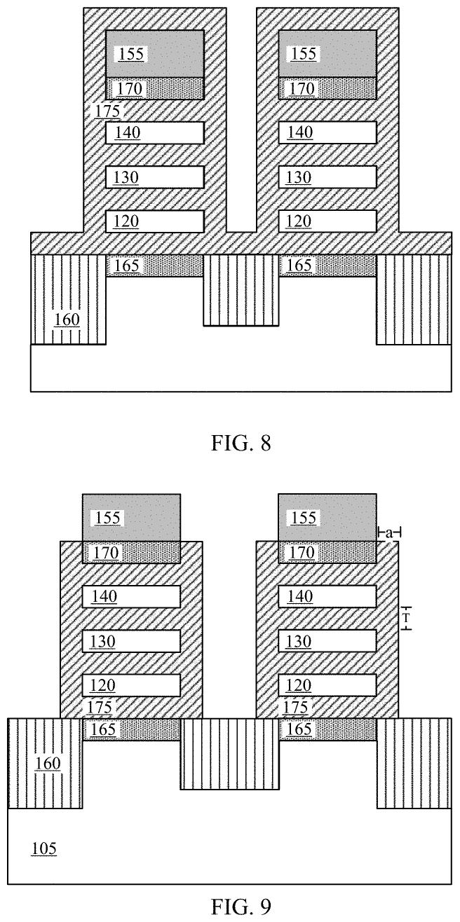

FIG. 8 illustrates cross sections Y₁, Y₂, and Y₃ of the nano device after formation of a uniform sacrificial layer, in accordance with the embodiment of the present invention. A uniformed sacrificial layer 175 is created by deposited material to combine the second layer 115, the fourth layer 125, the sixth layer 135, and the eighth layer 145 in to one layer. FIG. 9 illustrates cross section Y₁, Y₂, and Y₃ of the nano device after etching the uniform sacrificial layer 175, in accordance with the embodiment of the present invention. The uniformed sacrificial layer 175 is etched back to expose the hardmask 155 and to separate the nano stack columns from each other. The uniformed sacrificial layer 175 has a thickness of “a” when measured from the side of the nanosheets (the third layer 120, the fifth layer 130, and the seventh layer 140) to the sidewall of the uniformed sacrificial layer 175. The distance between the nanosheets is “T”. The thickness “a” of the uniformed sacrificial layer 175 is substantially equal to the distance “T” (i.e., the distance between the nanosheets).

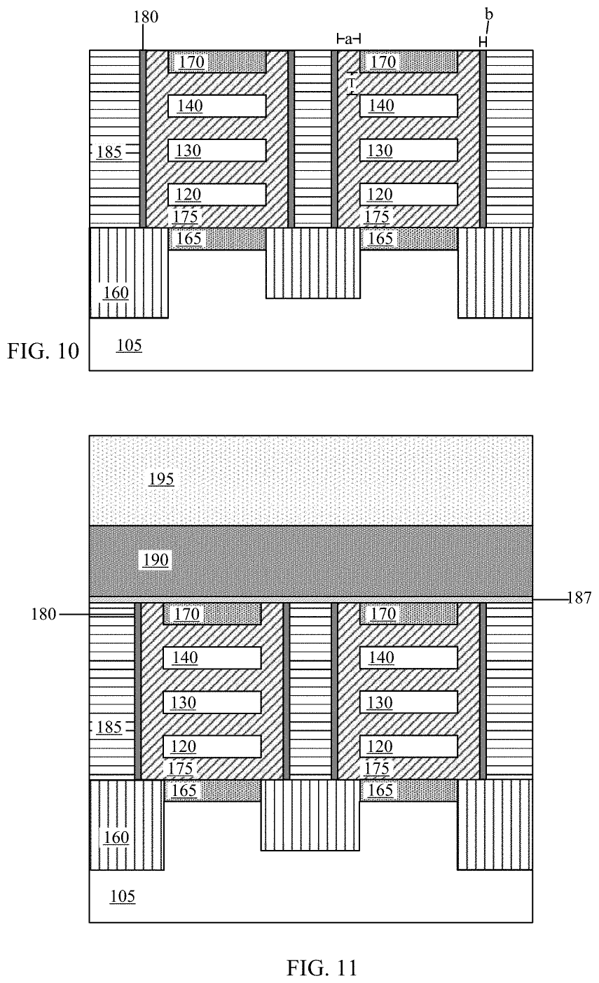

FIG. 10 illustrates cross sections Y₁, Y₂, and Y₃ of the nano device after formation of a dielectric liner 180 and a first dielectric layer 185, in accordance with the embodiment of the present invention. A dielectric liner 180 is formed along the sidewalls of the uniformed sacrificial layer 175. The dielectric liner 180 has a thickness “b”, where “b” is less than the thickness “a” of the uniformed sacrificial layer 175. The combined value of “b+a” is greater than the value of distance “T.” A first dielectric layer 185 is formed on top of the shallow trench isolation layer 160 and the first dielectric layer 185 is adjacent to the dielectric liner 180.

FIG. 11 illustrates cross section Y₁, Y₂, and Y₃ of the nano device after formation of an oxide liner 187, a dummy gate 190 and a second hardmask 195, in accordance with the embodiment of the present invention. An oxide liner 187 is formed on a top surface of the first dielectric layer 185, a top surface of the dielectric liner 180, a top surface of the uniformed sacrificial layer 175, and a top surface of the upper dielectric layer 170. A dummy gate 190 is formed on top of the oxide liner 187 and a second hardmask 195 is formed on top of the dummy gate 190.

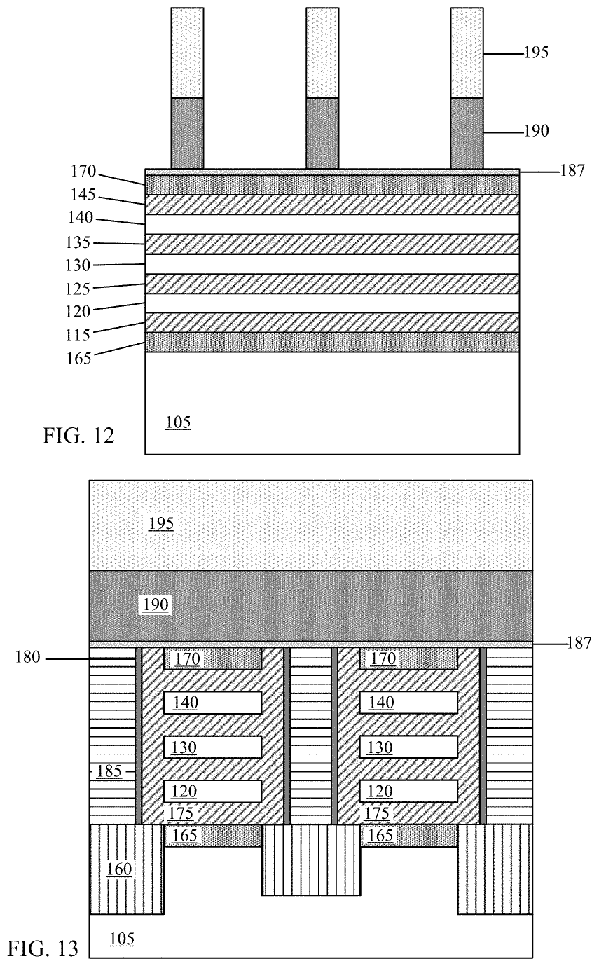

FIGS. 12, 13, 14 and 15 represent the structure after gate patterning. FIG. 12 illustrates cross section X of the nano device after patterning the dummy gate 190 and the second hardmask 195, in accordance with the embodiment of the present invention. The dummy gate 190 and the second hardmask 195 are patterned to form the gate regions. FIG. 13 illustrates cross section Y₁ of the nano device after patterning the dummy gate 190 and the second hardmask 195, in accordance with the embodiment of the present invention. The dummy gate 190 and the second hardmask 195 remain in place in the gate region as illustrated by FIG. 13.

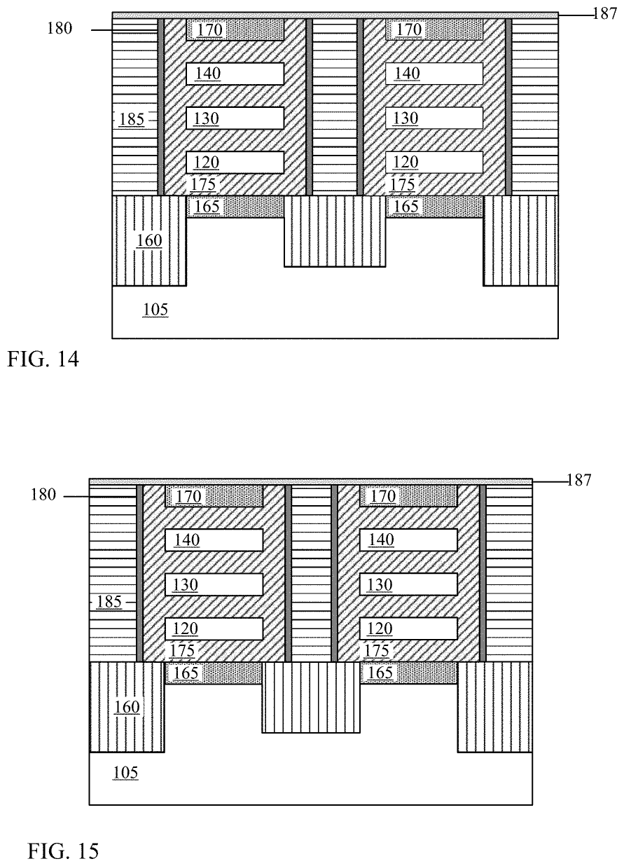

FIG. 14 illustrates cross section Y₂ of the nano device after patterning the dummy gate 190 and the second hardmask 195, in accordance with the embodiment of the present invention. FIG. 15 illustrates cross section Y₃ of the nano device after patterning the dummy gate 190 and the second hardmask 195, in accordance with the embodiment of the present invention. The dummy gate 190 and the second hardmask 195 are removed from the source/drain region.

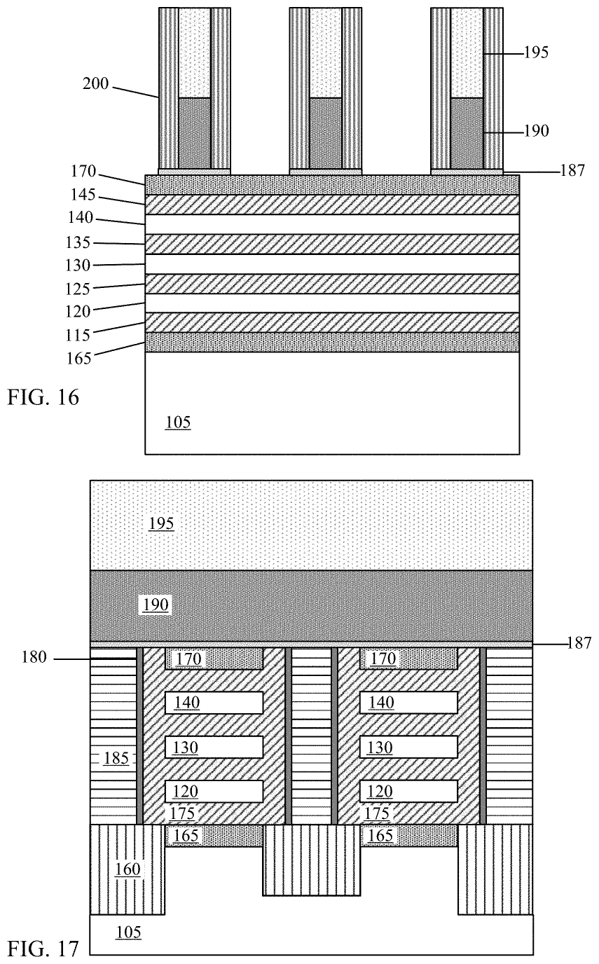

FIGS. 16, 17, 18 and 19 represent the structure after upper spacer formation. FIG. 16 illustrates cross section X of the nano device after formation of an upper spacer 200, in accordance with the embodiment of the present invention. An upper spacer 200 is formed on the exposed surfaces of the dummy gate 190, the oxide liner 187, and the second hardmask 195. The upper spacer 200 is etched back so that the upper spacer 200 remains on the sidewalls of the dummy gate 190 and the sidewalls of the second hardmask 195. The oxide liner 187 is removed during the etching of the upper spacer 200, but a portion of the oxide liner 187 remains beneath the dummy gate 190 and beneath the upper spacer 200.

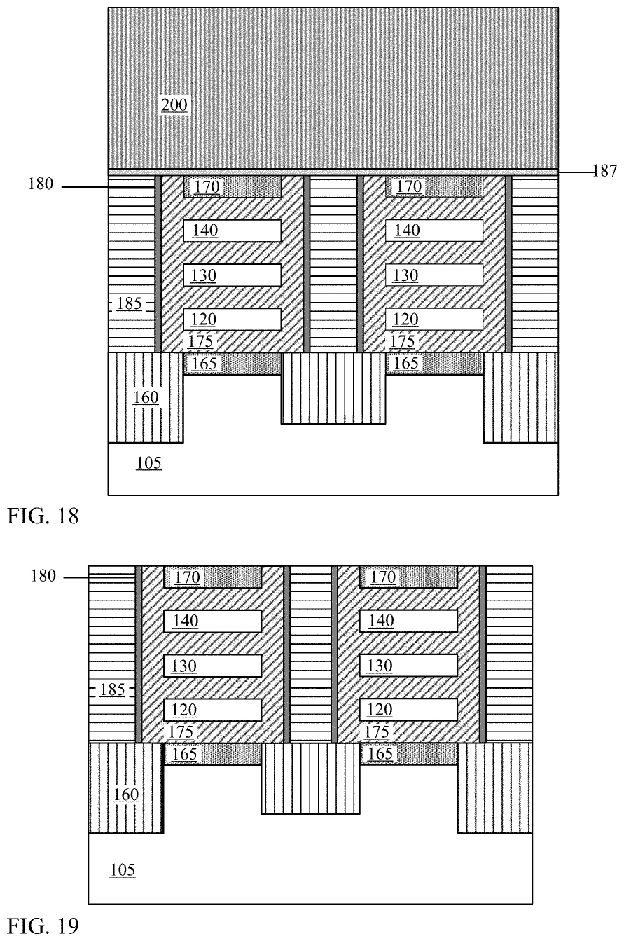

FIG. 17 illustrates cross section Y₁ of the nano device after formation of the upper spacer 200, in accordance with the embodiment of the present invention. FIG. 18 illustrates cross section Y₂ of the nano device after formation of the upper spacer 200, in accordance with the embodiment of the present invention. FIG. 18 illustrates a side region that is directly adjacent to the dummy gate 190, thus the upper spacer 200 is located on top of the oxide liner 187.

FIG. 19 illustrates cross section Y₃ of the nano device after pattering the formation of the upper spacer 200, in accordance with the embodiment of the present invention. The upper spacer 200 is removed from the source/drain region and the oxide liner 187 is also removed. The top surface of the first dielectric layer 185, the top surface of the dielectric liner 180, the top surface of the uniformed sacrificial layer 175, and the top surface of the upper dielectric layer 170 are exposed by the removal of the oxide liner 187.

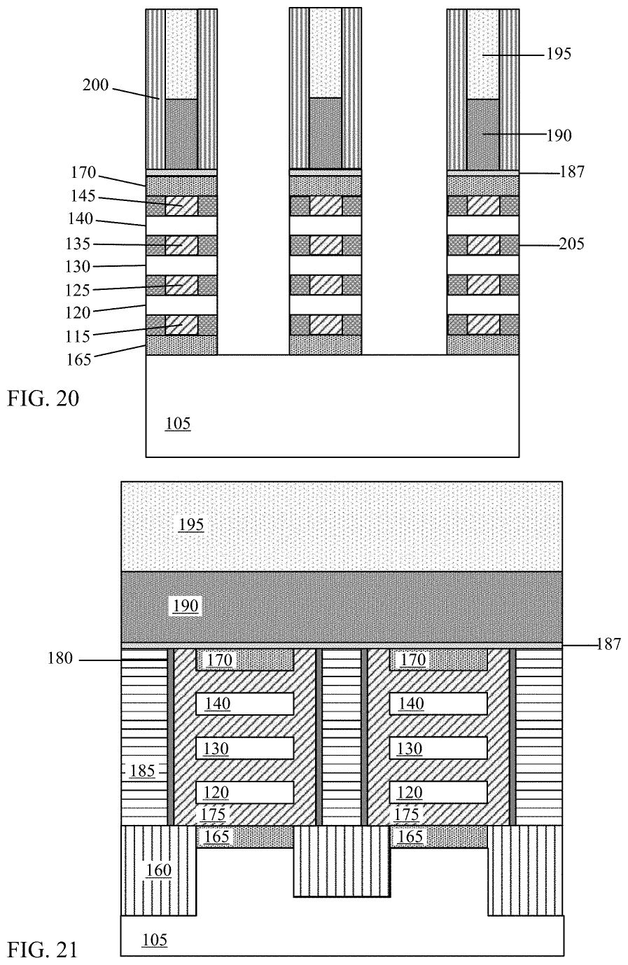

FIGS. 20, 21, 22 and 23 represent the structure after nanosheet stack recess and inner spacer formation. FIG. 20 illustrates cross section X of the nano device after etching the nano stack 107 to form a plurality of gate regions and after the formation of the inner spacer 205, in accordance with the embodiment of the present invention. The nano stack 107 has been etched to form a plurality of gate regions. The uniformed sacrificial layer 175 (which includes the second layer 115, the fourth layer 125, the sixth layer 135, and the eighth layer 145), is etched back to create a plurality of recesses. The recesses are located around the ends of the third layer 120, the fifth layer 130, and the seventh layer 140. The recess exposes the ends of the third layer 120, the fifth layer 130, and the seventh layer 140. An inner spacer 205 is formed inside the recesses, where the inner spacer 205 wraps around the ends of the third layer 120, the fifth layer 130, and the seventh layer 140.

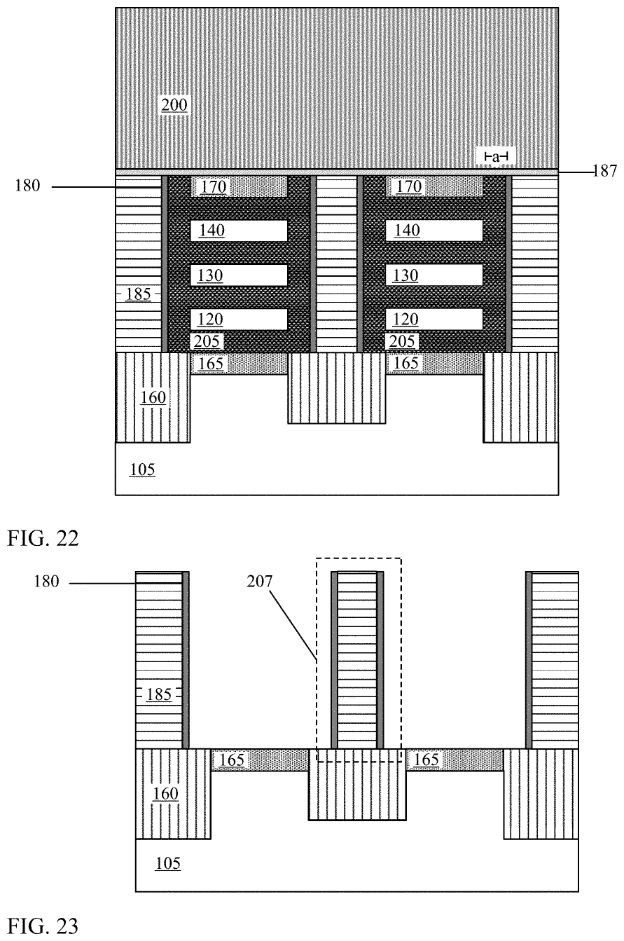

FIG. 21 illustrates cross section Y₁ of the nano device after etching the nano stack 107 to form a plurality of gate regions and after the formation of the inner spacer 205, in accordance with the embodiment of the present invention. FIG. 22 illustrates cross section Y₂ of the nano device after etching the nano stack to form a plurality of gate regions and after the formation of the inner spacer 205, in accordance with the embodiment of the present invention. The uniformed sacrificial layer 175 (which includes the second layer 115, the fourth layer 125, the sixth layer 135, and the eighth layer 145), is etched back to create a plurality of recesses. The recesses are located around the ends of the third layer 120, the fifth layer 130, and the seventh layer 140. The recess exposes the ends of the third layer 120, the fifth layer 130, and the seventh layer 140. An inner spacer 205 is formed inside the recesses, where the inner spacer 205 wraps around the ends of the third layer 120, the fifth layer 130, and the seventh layer 140. The inner spacer 205 is located adjacent to the dielectric liner 180. For example, the inner spacer 205 has a thickness of “a” when measured from the side of the nanosheets (the third layer 120, the fifth layer 130, and the seventh layer 140) to the dielectric liner 180. The thickness “a” of the inner spacer 205 is substantially equal to the thickness “a” of the uniformed sacrificial layer 175.

FIG. 23 illustrates cross section Y₃ of the nano device after removal of the uniformed sacrificial layer 175 and the nanosheets, in accordance with the embodiment of the present invention. The uniformed sacrificial layer 175, the third layer 120, the fifth layer 130, and the seventh layer 140 are removed to create space for the formation of a source/drain. The dielectric liner 180 remains located on the sidewalls of the first dielectric layer 185. Dashed box 207 emphasizes a column of the first dielectric layer 185 sandwiched between different sections of the dielectric liners 180. This section provides mechanical stability for nanodevices (ND1 and ND2) after the formation of the inner spacer 205.

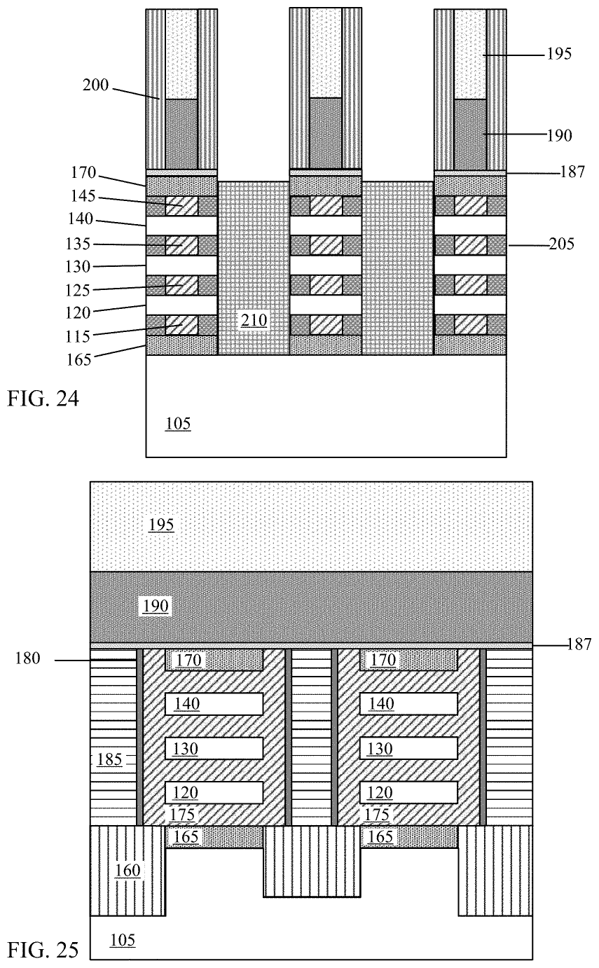

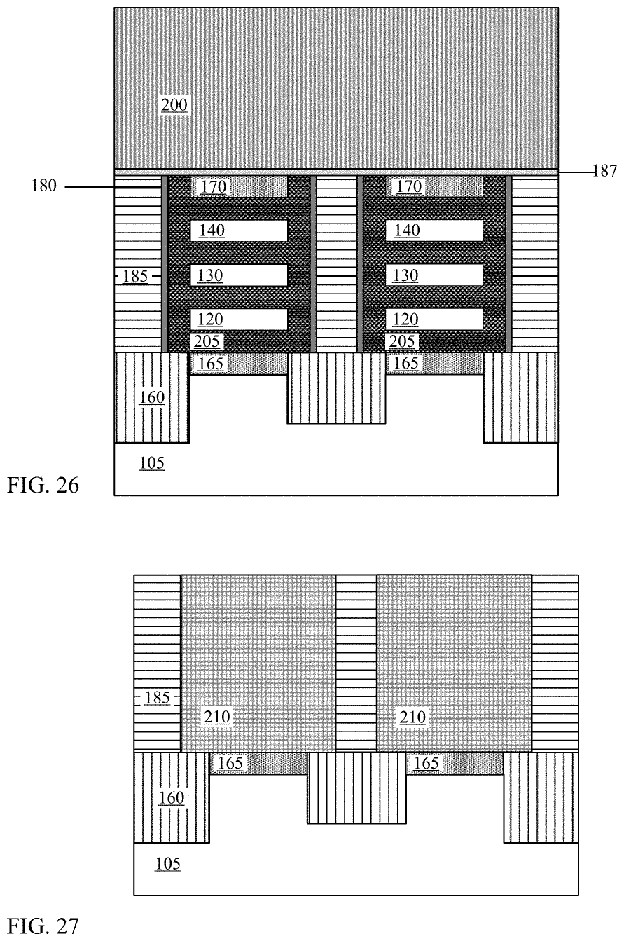

FIGS. 24, 25, 26 and 27 represent the structure after source/drain epi growth. FIG. 24 illustrates cross section X of the nano device after formation of the source/drain 210, in accordance with the embodiment of the present invention. FIG. 25 illustrates cross section Y₁ of the nano device after formation of the source/drain 210, in accordance with the embodiment of the present invention. FIG. 26 illustrates cross section Y₂ of the nano device after formation of the source/drain 210, in accordance with the embodiment of the present invention.

The source/drain 210 is formed in the source/drain region. The source/drain 210 can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

FIG. 27 illustrates cross section Y₃ of the nano device after formation of the source/drain 210, in accordance with the embodiment of the present invention. The dielectric liner 180 is removed prior to the formation of the source/drain 210. The source/drain 210 is formed between the sections of the first dielectric layer 185.

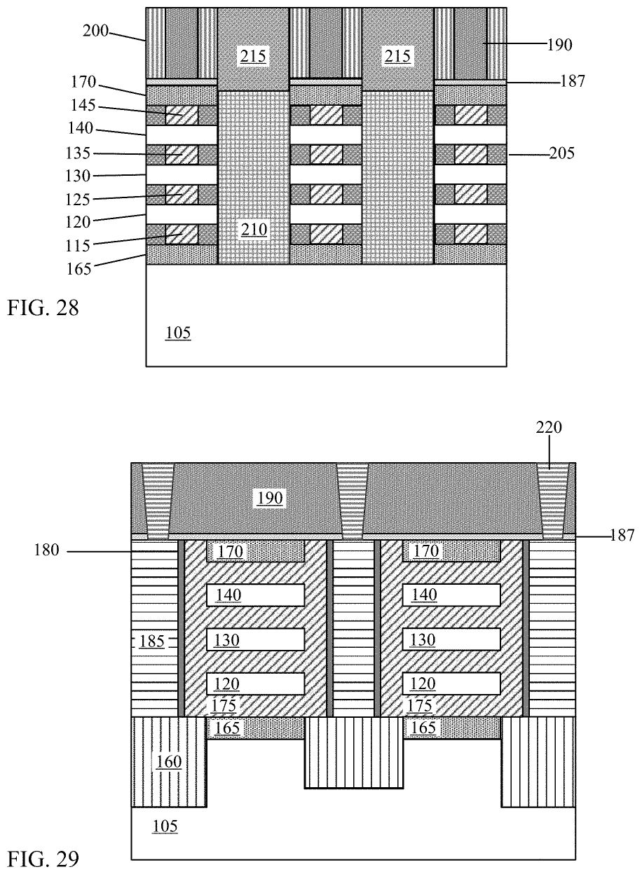

FIGS. 28, 29, 30 and 31 represent the structure after interlayer dielectric deposition and planarization, and gate cut formation. FIG. 28 illustrates cross section X of the nano device after formation of an interlayer dielectric 215, in accordance with the embodiment of the present invention. An interlayer dielectric 215 is formed on top of the source drain 210. The second hardmask 195, a portion of the upper spacer 200, and any excess interlayer dielectric 215 material is planarized by, for example, chemical mechanical planarization to create a uniform top surface.

FIG. 29 illustrates cross section Y₁ of the nano device after formation of gate cuts and a dielectric fill, in accordance with the embodiment of the present invention. Gate cuts 220 are made in the dummy gate 190, where the gate cut 220 extends downwards through the dummy gate 190 to the first dielectric layer 185. The gate cuts 220 are filled with a dielectric material.

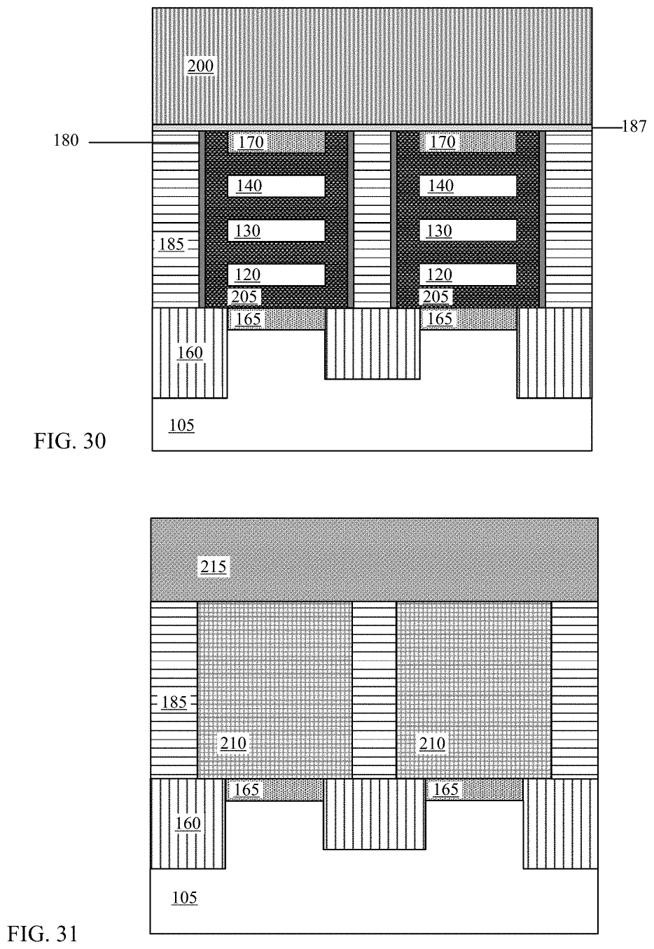

FIG. 30 illustrates cross section Y₂ of the nano device after formation of an interlayer dielectric 215, in accordance with the embodiment of the present invention. FIG. 31 illustrates cross section Y₃ of the nano device after formation of an interlayer dielectric 215, in accordance with the embodiment of the present invention. An interlayer dielectric 215 is formed on top of the source/drain 210 and on top of the first dielectric layer 185.

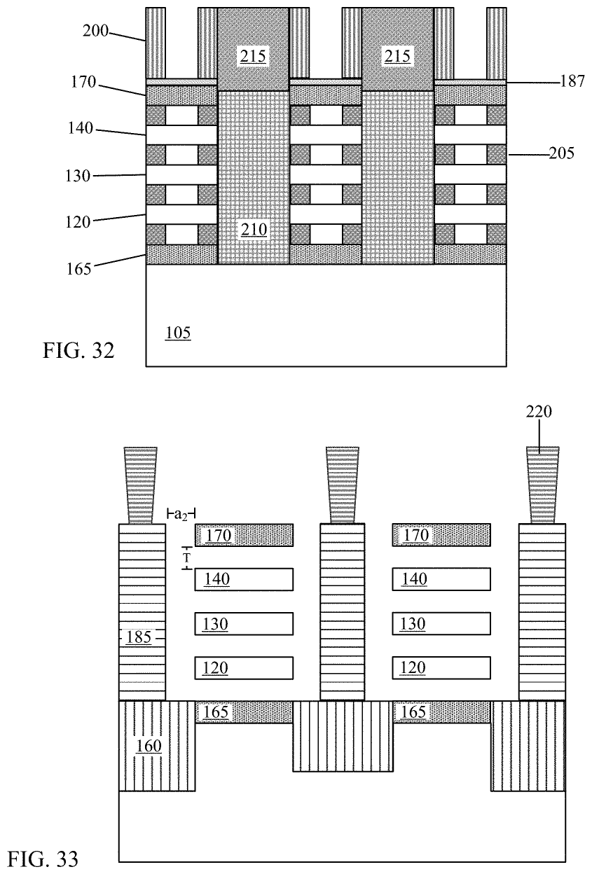

FIGS. 32, and 33 represent the structure after removal of the dummy gate 190 and the removal of the sacrificial layers and the dielectric liner 180. FIG. 32 illustrates cross section X of the nano device after removal of the dummy gate 190 and the removal of the sacrificial layers, in accordance with the embodiment of the present invention. The dummy gate 190 and the sacrificial layers (i.e., the second layer 115, the fourth layer 125, the sixth layer 135, and the eighth layer 145) are removed to create space for the formation of the gate.

FIG. 33 illustrates cross section Y₁ of the nano device after removal of the dummy gate 190 and the removal of the sacrificial layers and the dielectric liner 180, in accordance with the embodiment of the present invention. The dielectric liner 180 and the uniform sacrificial layer 175 are removed. For example, the distance between the sidewall of the seventh layer 140 is “a₂”. Distance “a₂” is larger than the spacing between the nanosheets “T”. Distance “a₂” is greater than distance “a” because the dielectric liner 180 was removed with the sacrificial layers. This larger distance (i.e., distance “a₂” is now larger than distance “T”) allows for the gate material have an easier time at filling the space between the nanosheets.

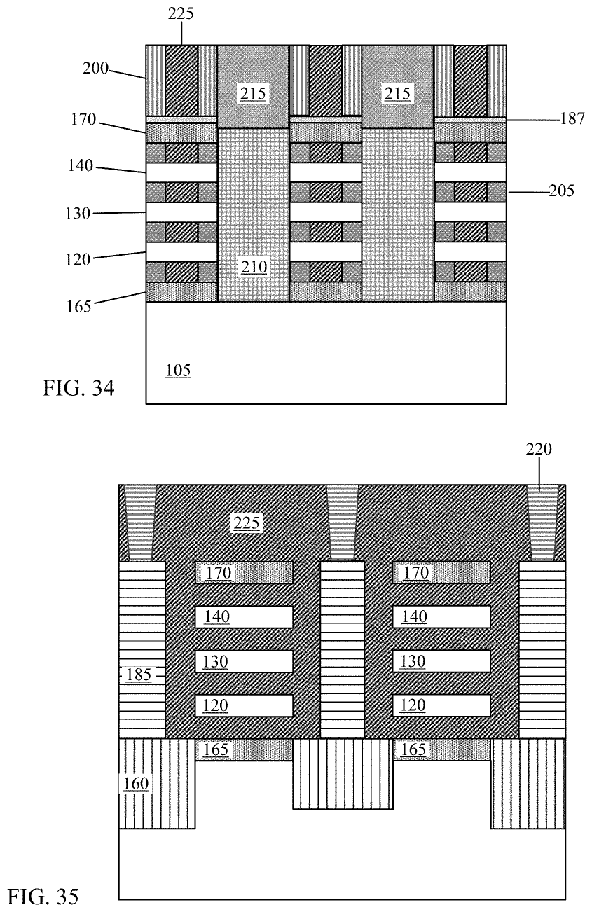

FIGS. 32, and 34 represent the structure after replacement high-k metal gate (HKMG) formation. FIG. 34 illustrates cross section X of the nano device after the formation of the gate, in accordance with the embodiment of the present invention. The gate 225 is formed in the space created by the removal of the dummy gate 190 and the sacrificial layers (i.e., the second layer 115, the fourth layer 125, the sixth layer 135, and the eighth layer 145). The gate 225 can be comprised of, for example, a gate dielectric liner, such as high-k dielectric like HfO₂, ZrO₂, HfLₐOₓ, etc., and work function layers, such as TiN, TiAlC, TiC, etc., and conductive metal fills, like W.

FIG. 35 illustrates cross section Y₁ of the nano device after the formation of the gate 225, in accordance with the embodiment of the present invention. The gate is formed around the nanosheets (i.e., the third layer 120, the fifth layer 130, and the seventh layer 140) and the upper dielectric layer 170. Furthermore, the gate 225 is formed around the gate cuts 220.

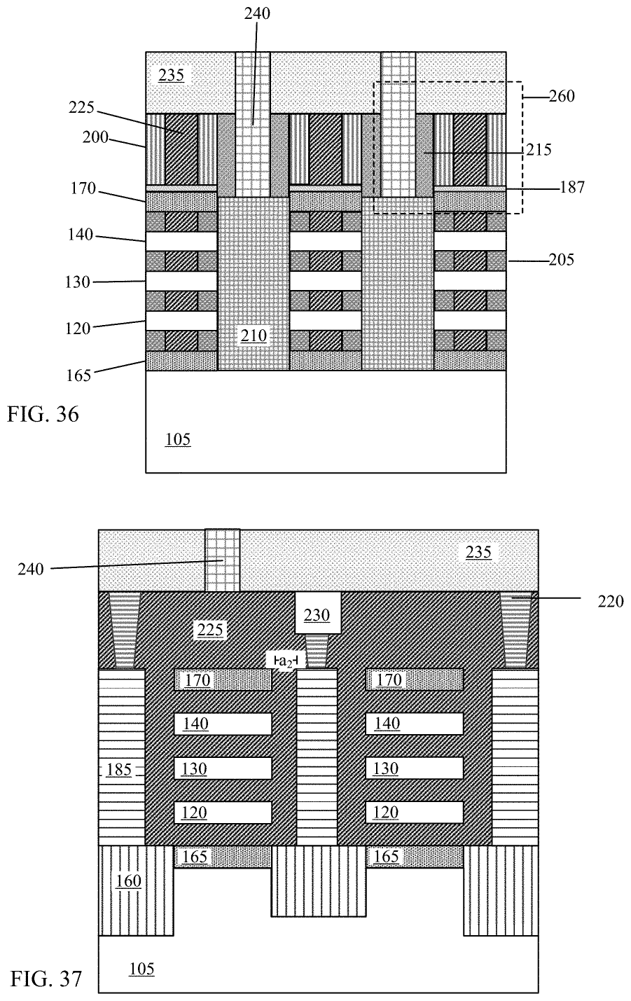

FIGS. 36, 37, 38 and 39 represent the structure after additional gate metal plug formation and middle of the line (MOL) contact formation. FIG. 36 illustrates cross section X of the nano device after formation of a second interlayer dielectric and a contact, in accordance with the embodiment of the present invention. A second interlayer dielectric 235 is formed on top of the exposed surfaces of the upper spacer 200, the gate 225, and the interlayer dielectric 215. A contact 240 is made by forming a trench in the second interlayer dielectric 235 and extends downwards through the interlayer dielectric 215 to the top surface of the source/drain 210. The trench is filled with a metal to form the contact 240.

FIG. 37 illustrates cross section Y₁ of the nano device after formation of a second interlayer dielectric 235, a contact 240, and a metal plug 230, in accordance with the embodiment of the present invention. FIG. 37 illustrates the situation where a shared gate is desired, but this is not necessary to form the shared gate. The shared gate is formed by etching a trench in the gate cut 220 between devices. A metal plug 230 is formed in the trench. The metal plug 230 acts as a connector thus the separate gates 225 becomes a shared gate 225. A second interlayer dielectric 235 is formed on top of the gate 225 and on top of the gate cuts 220. When a metal plug 230 is present (as illustrated), then the second interlayer dielectric 235 is formed on top of the metal plug 230. A contact 240 is formed in the second interlayer dielectric 235.

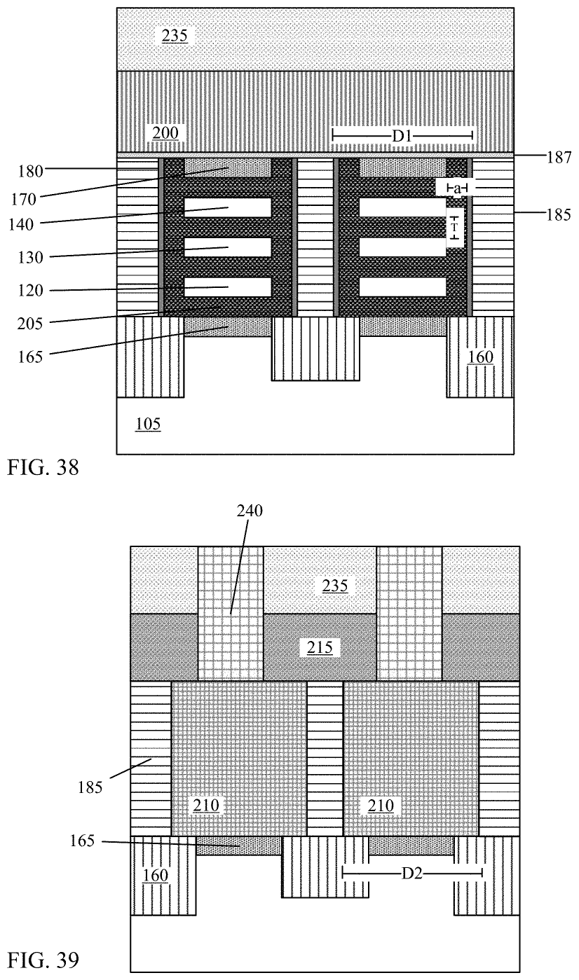

FIG. 38 illustrates cross section Y₂ of the nano device after formation of a second interlayer dielectric 235, in accordance with the embodiment of the present invention. The second interlayer dielectric 235 is formed on top of the upper spacer 200. FIG. 39 illustrates cross section Y₃ of the nano device after formation of a second interlayer dielectric and a contact, in accordance with the embodiment of the present invention. The second interlayer dielectric 235 is formed on top of the source/drain 210 and on top of the first dielectric layer 185. A contact 240 is formed in the second interlayer dielectric 235, where the contact 240 extends downwards to the source/drain 210. The distance D1 represents the distance from one section of the dielectric liner 180 to another section of the dielectric liner 180 (i.e., the combined length/thickness of a first section of the dielectric liner 180, a first section of the inner spacer 205, the seventh layer 140 or upper dielectric layer 170, a second section of the inner spacer 205, and a second section the dielectric liner 180). The width of the source/drain 210 is distance D2, where distance D2 is substantial equal to distance D1.

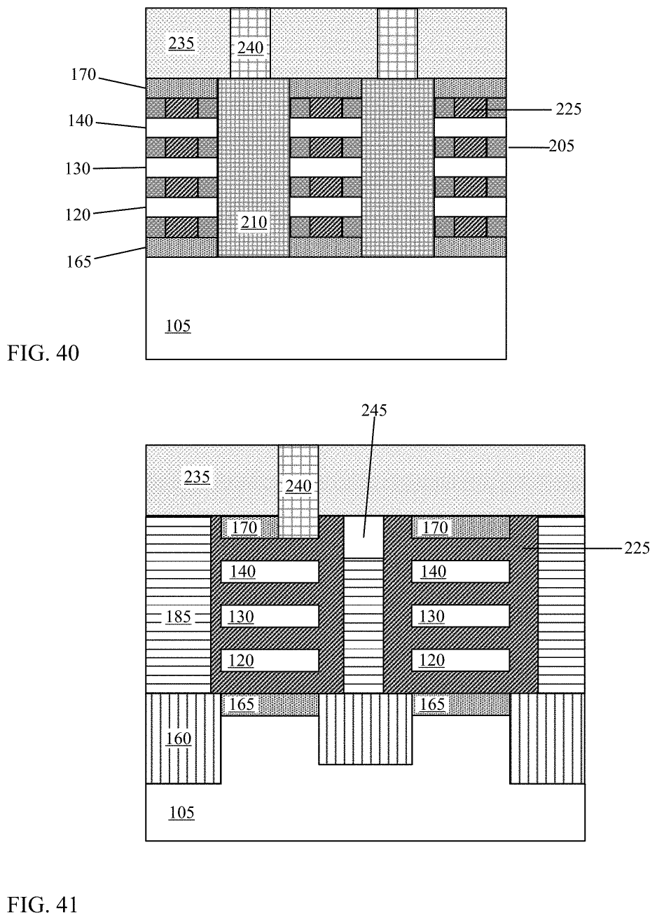

FIGS. 40, 41, 42 and 43 represent an alternative structure after additional gate metal plug formation and MOL contact formation. FIG. 40 illustrates cross section X of the nano device after formation of a second interlayer dielectric 235 and a contact 240, in accordance with the embodiment of the present invention. The devices are planarized to reduce the height of the device. A uniform surface is created along the top of the upper dielectric layer 170 and the top of source/drain 210. The second interlayer dielectric 235 is formed on the uniformed surface along the top of the upper dielectric layer 170 and the top of source/drain 210. A contact 240 is formed in the second interlayer dielectric 235 to connected to the source/drain 210.

FIG. 41 illustrates cross section Y₁ of the nano device after formation of a second interlayer dielectric 235, a contact 240, and a metal plug 245, in accordance with the embodiment of the present invention. FIG. 41 illustrates the situation where a shared gate is desired, but this is not necessary to form the shared gate. The shared gate is formed by etching a trench in the in the first dielectric layer 185 located between two adjacent devices. A metal plug 245 is formed in the trench in the first dielectric layer 185. The metal plug 245 acts as a connector thus the separate gates 225 becomes a combined/shared gate 225. A contact 240 extends downwards through the second interlayer dielectric 235 and through the upper dielectric layer 170 to connected to the gate 225. The embodiment as illustrated by FIGS. 36 to 39 a parasitic capacitor can be formed between the source/drain contacts 240 and the gate 225, as illustrated by dashed box 260. The embodiment as illustrated by FIGS. 40 to 43 a parasitic capacitor is not formed between the source/drain contacts 240 and the gate 225, since there is no overlap between the source/drain contact 240 and the gate 225.

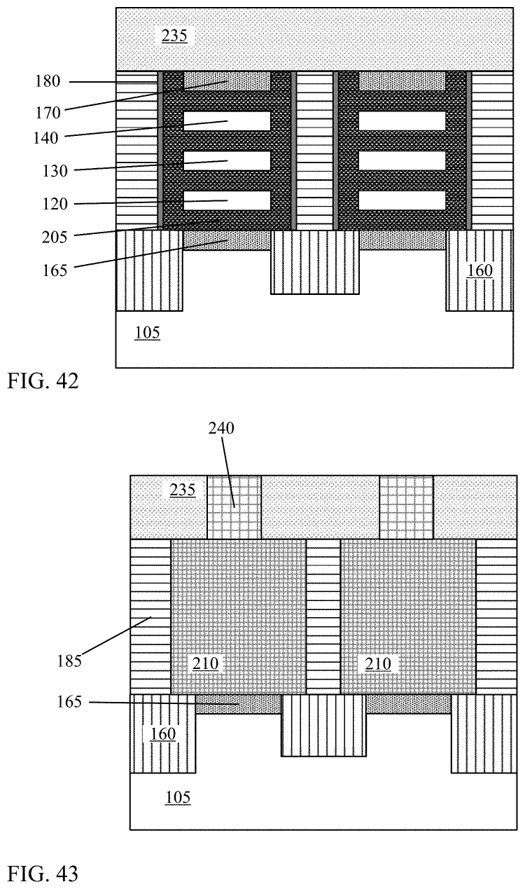

FIG. 42 illustrates cross section Y₂ of the nano device after formation of a second interlayer dielectric, in accordance with the embodiment of the present invention. The second interlayer dielectric 235 is formed on top first dielectric layer 185, dielectric liner 180, upper dielectric layer 170, and on top of the inner spacer 205. FIG. 43 illustrates cross section Y₃ of the nano device after formation of a second interlayer dielectric and a contact, in accordance with the embodiment of the present invention. The second interlayer dielectric 235 is formed on top of the source/drain 210 and on top of the first dielectric layer 185. A contact 240 is formed in the second interlayer dielectric 235, where the contact 240 extend downwards to the source/drain 210.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A semiconductor device comprising:
a nanodevice located on a substrate, wherein the nanodevice includes a plurality of nanosheets, wherein each of the plurality of nanosheets are spaced apart from each other by a first distance;
a gate located on the substrate, wherein the gate surrounds each of the plurality of nanosheets;
a first dielectric layer located on the substrate, wherein the first dielectric layer is located adjacent to a sidewall of the gate, wherein the gate has a first thickness when measured from the sidewall of one of the plurality of nanosheets to a sidewall of the first dielectric layer, wherein the first thickness is larger than the first distance; and
an inner spacer located on the substrate, wherein the inner spacer wraps around an end of each of the plurality of nanosheets, wherein the inner spacer has a second thickness, wherein the second thickness is substantially equal to the first distance.

2. The semiconductor device of claim 1, wherein the first dielectric layer is adjacent to the inner spacer.

3. The semiconductor device of claim 2, further comprising:
a dielectric liner located on the substrate, wherein the dielectric liner is directly adjacent to the inner spacer and directly adjacent to the first dielectric layer.

4. The semiconductor device of claim 3, wherein the dielectric liner has a third thickness.

5. The semiconductor device of claim 4, wherein the sum of the second thickness and the third thickness is larger than the first distance.

6. The semiconductor device of claim 4, wherein a sum of the second thickness and the third thickness is substantially equal to the first thickness.

7. The semiconductor device of claim 4, further comprising:
a source/drain located on the substrate, wherein the source/drain is located adjacent to the inner spacer.

8. The semiconductor device of claim 7, further comprising:
an interlayer dielectric layer located on top of the source/drain; and
a contact extending through the interlayer dielectric layer to connected with the source/drain.

9. A semiconductor device comprising:
a first nanodevice located on a substrate, wherein the first nanodevice includes a plurality of first nanosheets, wherein each of the plurality of first nanosheets are spaced apart from each other by a first distance;
a second nanodevice located on the substrate, wherein the second nanodevice includes a plurality of second nanosheets, wherein each of the plurality of second nanosheets are spaced apart from each other by the first distance;
a first gate located on the substrate, wherein the first gate surrounds each of the plurality of first nanosheets;
a second gate located on the substrate, wherein the second gate surrounds each of the plurality of second nanosheets;
a first dielectric layer isolation pillar located on the substrate, wherein the first dielectric isolation pillar is located between the first gate and the second gate;
a first dielectric layer located on the substrate, wherein the first dielectric layer is located around the first gate of the first nanodevice and the second gate of the second nanodevice, wherein the first dielectric layer is located adjacent to a sidewall of the first gate and adjacent to a sidewall of the second gate, wherein the first gate has a first thickness when measured from the sidewall of one of the plurality of first nanosheets to a sidewall of the first dielectric layer, wherein the first thickness is larger than the first distance; and
an inner spacer located on the substrate, wherein the inner spacer wraps around an end of each of the plurality of first nanosheets and wraps around an end of each of the plurality of second nanosheets, wherein the inner spacer has a second thickness, wherein the second thickness is substantially equal to the first distance.

10. The semiconductor device of claim 9, wherein the first dielectric layer is adjacent to the inner spacer.

11. The semiconductor device of claim 10, further comprising:
a dielectric liner located on the substrate, wherein the dielectric liner is directly adjacent to the inner spacer and directly adjacent to the first dielectric layer.

12. The semiconductor device of claim 11, wherein the dielectric liner has a third thickness.

13. The semiconductor device of claim 12, wherein a sum of the second thickness and the third thickness is larger than the first distance.

14. The semiconductor device of claim 13, wherein the sum of the second thickness and the third thickness is substantially equal to the first thickness.

15. The semiconductor device of claim 14, further comprising:
a source/drain located on the substrate, wherein the source/drain is located adjacent to the inner spacer.

16. The semiconductor device of claim 15, further comprising:
an interlayer dielectric layer located on top of the source/drain; and
a contact extending through the interlayer dielectric layer to connected with the source/drain.

17. The semiconductor device of claim 9, further comprising:
a metal plug located in the first dielectric isolation pillar, wherein the metal plug is in contact with the first gate and the second gate.

18. A method of forming a nanodevice comprising:
forming a plurality of nanosheets and plurality of sacrificially layers, wherein one sacrificial layer of the plurality of sacrificial layers is located above and below each of the plurality of nanosheets, wherein each of the plurality of nanosheets are spaced apart from each other by a first distance;
forming a shared sacrificial layer that combines each of the sacrificial layers of the plurality of sacrificial layers, wherein the shared sacrificial layer has a first thickness when measured from a sidewall of one of nanosheets to a sidewall of the shared sacrificial layer, wherein the first thickness is equal to the first distance;
forming a dielectric liner along the sidewalls of the shared sacrificial layer;
forming a first dielectric layer around the dielectric liner;
recessing the shared sacrificial layers at the end of the plurality of the nanosheets to create spacer for the formation of an inner spacer;
forming an inner spacer around the ends of each of the plurality of nanosheets, wherein the inner spacer has a second thickness when measured from a sidewall of one of nanosheets to a sidewall of the dielectric liner, wherein the second thickness is equal to the first distance; and
removing the shared sacrificial layer and the dielectric liner in a gate region of the nanodevice and forming a gate around each of the plurality of nanosheets, wherein the gate has a third thickness when measured from a sidewall of one of nanosheets to a sidewall of the gate, wherein the third thickness is greater than the first distance.

19. The method of forming the nanodevice of claim 18, wherein the dielectric liner has a fourth thickness.

20. The method of forming the nanodevice of claim 19, wherein a sum of the fourth thickness and the second thickness is larger than the first distance.
